(19) United States
(12) Patent Application Publication
(10) Pub. No.: US 2026/0305376 A1
(43) Pub. Date: Oct. 1, 2026

(54) SEMICONDUCTOR DEVICE AND METHOD OF MANUFACTURING THE SAME

(71) Applicant: Renesas Electronics Corporation, Tokyo (JP)

(72) Inventors: Takuya KADOGUCHI, Tokyo (JP); Takamichi HOSOKAWA, Tokyo (JP); Kuniharu MUTO, Tokyo (JP); Tetsu NEGISHI, Tokyo (JP); Mikiya CHONABAYASHI, Tokyo (JP); Saki WAKABAYASHI, Tokyo (JP)

(21) Appl. No.: 19/571,662

(22) Filed: Mar. 19, 2026

(30) Foreign Application Priority Data
Mar. 28, 2025 (JP) 2025-056826

(51) Int. Cl. H10W 70/20; H10W 40/20; H10W 40/25; H10W 70/02; H10W 72/30; H10W 74/10; H10W 90/00

(52) U.S. Cl. CPC H10W 70/24; H10W 40/233; H10W 40/255; H10W 70/02; H10W 72/352; H10W 74/114; H10W 90/734

(57) ABSTRACT

A semiconductor device includes an insulating substrate, a first copper plate bonded to an upper surface of the insulating substrate, and a second copper plate bonded to a lower surface of the insulating substrate. Also, the semiconductor device includes at least one semiconductor chip bonded to the first copper plate via a metal layer made of silver and a sealing body formed to seal the semiconductor chip and the insulating substrate. An upper surface of the first copper plate, a side surface of the first copper plate, and a side surface of the second copper plate are each roughened.

### CROSS-REFERENCE TO RELATED APPLICATIONS

The disclosure of Japanese Patent Application No. 2025-056826 filed on Mar. 28, 2025 including the specification, drawings and abstract is incorporated herein by reference in its entirety.

### BACKGROUND

The present invention relates to a semiconductor device and a method of manufacturing the same.

There is disclosed a technique listed below.

[Patent Document 1] Japanese Unexamined Patent Application Publication No. 2010-245417

As a method of suppressing separation between a die pad on which a semiconductor device is mounted and an insulating resin that seals the die pad, there is known a technique of roughening an upper surface of the die pad (see Patent Document 1).

### SUMMARY

In the case of a semiconductor device in which a semiconductor chip is mounted on a copper plate, it is desirable to improve connection reliability between the semiconductor chip and the copper plate. In addition, when an insulating resin that seals the semiconductor chip and the copper plate are in close contact with each other, it is desirable to prevent separation at an adhesion interface between the copper plate and the insulating resin.

Other problems and novel features will become apparent from the description of this specification and the accompanying drawings.

A semiconductor device according to one embodiment includes an insulating substrate, a first copper plate bonded to an upper surface of the insulating substrate, and a second copper plate bonded to a lower surface of the insulating substrate. Also, the semiconductor device includes at least one semiconductor chip bonded to the first copper plate via a metal layer made of silver and an insulating resin formed to seal the semiconductor chip and the insulating substrate. An upper surface of the first copper plate, a side surface of the first copper plate, and a side surface of the second copper plate are each roughened.

A method of manufacturing a semiconductor device according to another embodiment includes preparing a first substrate and mounting at least one semiconductor chip on the first substrate via a metal layer made of silver. The first substrate includes a first copper plate bonded to an upper surface of an insulating substrate and a second copper plate bonded to a lower surface of the insulating substrate. An upper surface of the first copper plate, a side surface of the first copper plate, and a side surface of the second copper plate are each roughened.

According to the above embodiment, it is possible to improve performance of a semiconductor device.

### BRIEF DESCRIPTION OF THE DRAWINGS

FIG. 1 is a top view of a semiconductor device according to one embodiment.

FIG. 2 is a transparent plan view illustrating an internal structure of the semiconductor device in a state where a sealing body illustrated in FIG. 1 is seen through.

FIG. 3 is a cross-sectional view taken along a line A-A in FIG. 1.

FIG. 4 is an explanatory diagram for describing a method of calculating a maximum valley depth (Sv), which is an evaluation index of surface roughness.

FIG. 5 is a cross-sectional view illustrating a modification of the semiconductor device illustrated in FIG. 3.

FIG. 6 is a cross-sectional view illustrating a modification of the semiconductor device illustrated in FIG. 5.

FIG. 7 is a cross-sectional view illustrating a modification of the semiconductor device illustrated in FIG. 6.

FIG. 8 is a cross-sectional view illustrating another modification of the semiconductor device illustrated in FIG. 1.

FIG. 9 is a cross-sectional view illustrating another modification of the semiconductor device illustrated in FIG. 1.

FIG. 10 is a cross-sectional view illustrating a state in which a cooler is connected to a lower surface of the semiconductor device illustrated in FIG. 9.

FIG. 11 is an explanatory diagram illustrating an example of a flow of a manufacturing process of the semiconductor device according to one embodiment.

FIG. 12 is a cross-sectional view illustrating an example of a substrate prepared in a substrate preparation step illustrated in FIG. 11.

FIG. 13 is a cross-sectional view illustrating a state in which surfaces of copper plates bonded to an insulating substrate are roughened in the substrate preparation step illustrated in FIG. 11.

FIG. 14 is a cross-sectional view illustrating a state in which a mask is formed such that a chip mounting region of the copper plate illustrated in FIG. 13 is exposed in the substrate preparation step illustrated in FIG. 11.

FIG. 15 is a cross-sectional view illustrating a state in which a silver plating layer is selectively formed in the chip mounting region of the copper plate illustrated in FIG. 14 in the substrate preparation step illustrated in FIG. 11.

FIG. 16 is a cross-sectional view illustrating a state in which a mask is formed such that a chip mounting region of a copper plate bonded to an upper surface of an insulating substrate is exposed in the substrate preparation step illustrated in FIG. 11.

FIG. 17 is a cross-sectional view illustrating a state in which a silver plating layer is selectively formed in the chip mounting region of the copper plate illustrated in FIG. 16 in the substrate preparation step illustrated in FIG. 11.

FIG. 18 is a cross-sectional view illustrating a state in which a mask is selectively formed so as to cover the silver plating layer in the chip mounting region illustrated in FIG. 17 in the substrate preparation step illustrated in FIG. 11.

FIG. 19 is a cross-sectional view illustrating a state in which surfaces of the copper plates are roughened while the silver plating layer is covered with the mask in the substrate preparation step illustrated in FIG. 11.

FIG. 20 is a cross-sectional view illustrating a state in which a mask is formed so as to selectively cover a chip mounting region of a copper plate bonded to an upper surface of an insulating substrate in the substrate preparation step illustrated in FIG. 11.

FIG. 21 is a cross-sectional view illustrating a state in which surfaces of the copper plates are roughened while the chip mounting region is covered with the mask in the substrate preparation step illustrated in FIG. 11.

FIG. 22 is a cross-sectional view illustrating a state in which the roughening mask illustrated in FIG. 21 is removed, and a plating mask is then formed such that the chip mounting region is exposed in the substrate preparation step illustrated in FIG. 11.

FIG. 23 is a cross-sectional view illustrating a state in which a silver plating layer is selectively formed in the chip mounting region of the copper plate illustrated in FIG. 22 in the substrate preparation step illustrated in FIG. 11.

### DETAILED DESCRIPTION

### Explanation of Description Form, Basic Terminology, and Usage in This Application

In this application, the embodiment will be described in a plurality of sections or the like as needed. However, these are not independent and irrelevant to each other unless otherwise stated. The plurality of sections or the like serves as each part of a single example, and a part of one section relates to the other section as details or a part or the entire of a modification regardless of the order of description. Also, the repetitive description of similar parts will be omitted in principle. Further, the constituent elements in the embodiment are not always indispensable unless otherwise stated or except for the case where the constituent elements are theoretically limited to that number or the constituent elements are obviously indispensable from the context.

Likewise, in the description of the embodiment or the like, the phrase “X made of A” for a material, a composition or the like is not intended to exclude those containing elements other than A except for the case where it is clearly limited or evidently limited from the context. For example, as for a component, it means “X containing A as a main component”. For example, a “silicon member” or the like is not limited to pure silicon and the silicon member includes a member made of silicon germanium (SiGe) alloy, a member made of multicomponent alloy containing silicon as a main component, and a member containing other additives or the like. In addition, when mentioning a gold plating layer, a Cu layer, nickel plating or the like, it includes a member containing gold, Cu, nickel, or the like as a main component as well as a pure one unless otherwise specified clearly.

In addition, when referring to a specific value or amount, the value or the like is described as an example except for the case where the value or the like is clearly limited or evidently limited from the context.

Further, in the drawings for the embodiment, the same or similar components are denoted by the same or similar reference characters or reference numerals, and the descriptions thereof are not repeated in principle.

In addition, in the accompanying drawings, hatching may be omitted even in cross-sections. Furthermore, even in the cases other than the cross-section, hatching or dot pattern may be applied so as to clarify that a portion is not a vacant space or clearly illustrate the boundary between regions.

The technique described in the following embodiment can be widely applied to a semiconductor device in which a semiconductor chip mounted on a copper plate on an insulating substrate is sealed by a sealing body. In the embodiment, as an example, a representative mode in which the technique is applied to a semiconductor device of a type in which leads protrude from two opposing sides among four sides of a sealing body having a quadrilateral shape in plan view will be described.

### Semiconductor Device

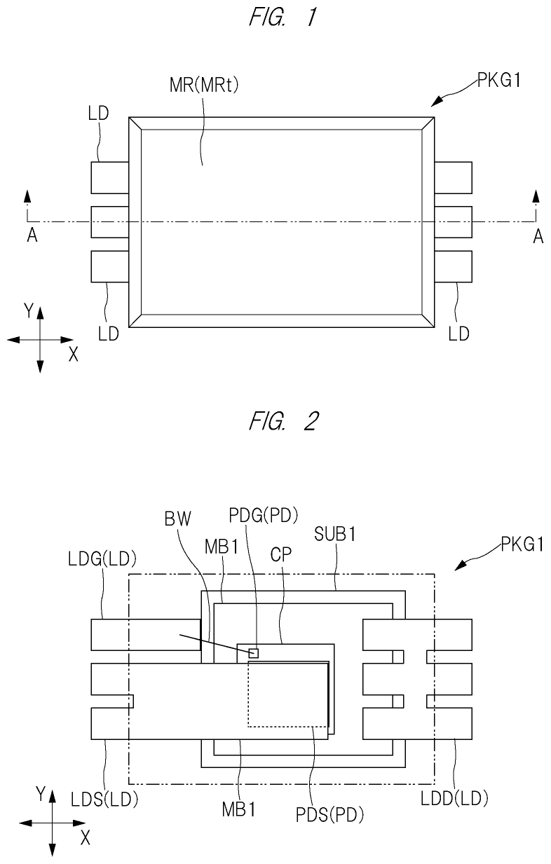

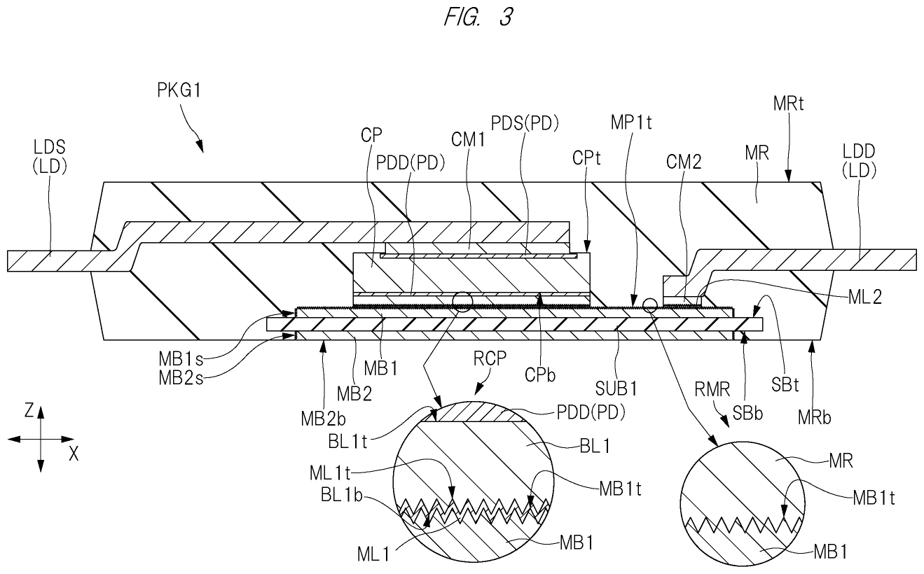

First, an outline of a configuration of a semiconductor device PKG1 according to this embodiment will be described with reference to FIG. 1 to FIG. 4. FIG. 1 is a top view of a semiconductor device according to one embodiment. FIG. 2 is a transparent plan view illustrating an internal structure of the semiconductor device in a state where a sealing body illustrated in FIG. 1 is seen through. FIG. 3 is a cross-sectional view taken along a line A-A in FIG. 1.

In FIG. 1 to FIG. 3, any of an X direction, a Y direction (see FIG. 1 and FIG. 2), and a Z direction (see FIG. 3) is indicated. The Y direction is a direction intersecting with the X direction, and the X direction and the Y direction are orthogonal to each other in the following description. The Z direction is a direction orthogonal to each of the X direction and the Y direction. In other words, the Z direction is a normal direction (in other words, a vertical direction) with respect to an X-Y plane including the X direction and the Y direction. In the following description, the term “thickness” refers to a length in the Z direction in principle. In addition, in the following description, the term “plan view” refers to a view of the X-Y plane in principle.

As illustrated in FIG. 1, the semiconductor device PKG1 includes a sealing body (insulating resin) MR and a plurality of leads LD exposed from side surfaces of the sealing body MR. In the example illustrated in FIG. 1, the sealing body MR has a quadrilateral shape in plan view.

The sealing body MR is mainly made of a resin material containing a thermosetting resin. The sealing body MR may contain filler particles such as silica in addition to the insulating resin. When filler particles such as silica are contained in the sealing body MR, a difference between a linear expansion coefficient of the sealing body MR and a linear expansion coefficient of a semiconductor chip CP (see FIG. 3) can be reduced. In addition, the sealing body MR may contain a black pigment in addition to the insulating resin. As illustrated in FIG. 1, the sealing body MR provided in the semiconductor device PKG1 has a quadrilateral planar shape. As illustrated in FIG. 3, the sealing body MR has an upper surface MRt and a lower surface MRb located opposite to the upper surface MRt.

As illustrated in FIG. 2 and FIG. 3, the semiconductor device PKG1 includes an insulating substrate SUB1, a copper plate MB1, and a copper plate MB2 (see FIG. 3). Each of the copper plate MB1 and the copper plate MB2 is a plate-shaped metal film made of copper or a copper alloy. As illustrated in FIG. 3, the insulating substrate SUB1 has an upper surface SBt and a lower surface SBb located opposite to the upper surface SBt. The copper plate MB1 is bonded to the upper surface SBt of the insulating substrate SUB1. The copper plate MB2 is bonded to the lower surface SBb of the insulating substrate SUB1.

As illustrated in FIG. 1 to FIG. 3, the semiconductor device PKG1 includes the plurality of leads LD. Each of the leads LD serves as an external terminal of the semiconductor device PKG1. As illustrated in FIG. 1, each of the leads LD protrudes from side surfaces of the sealing body MR to outside in plan view.

As illustrated in FIG. 2 and FIG. 3, the semiconductor device PKG1 includes at least one semiconductor chip CP. In the example illustrated in FIG. 2 and FIG. 3, the semiconductor device PKG1 includes one semiconductor chip CP.

The semiconductor device PKG1 according to this embodiment is a so-called power semiconductor device incorporated into a power supply circuit (not illustrated). The semiconductor chip CP (see FIG. 2) included in the semiconductor device PKG1 is, for example, a power semiconductor chip having a power transistor.

In this embodiment, the semiconductor chip CP includes a metal-oxide-semiconductor field-effect transistor (MOSFET) as an example. However, the semiconductor element included in the semiconductor chip CP is not limited to a MOSFET, and various modifications may be applied. For example, a modification of the semiconductor chip CP includes an insulated gate bipolar transistor (IGBT). Another modification of the semiconductor chip CP includes a diode.

The semiconductor element operable as the transistor or the diode described above is formed on a main surface of a semiconductor substrate (not illustrated) provided in the semiconductor chip CP. The semiconductor substrate is made of, for example, silicon or silicon carbide. The semiconductor element formed on the main surface of the semiconductor substrate is connected to pads PD formed on at least one of an upper surface CPt and a lower surface CPb of the semiconductor chip.

As illustrated in FIG. 2, the semiconductor chip CP has a quadrilateral shape in plan view. As illustrated in FIG. 3, the semiconductor chip CP has the upper surface CPt and the lower surface CPb located opposite to the upper surface CPt. A plurality of pads (electrode pads) PD is arranged on the upper surface CPt (see FIG. 3) of the semiconductor chip CP.

In this embodiment, the plurality of pads PD includes a source pad PDS and a gate pad PDG. The source pad PDS is electrically connected to a source of the MOSFET included in the semiconductor chip CP. The source pad PDS functions as a source electrode of the MOSFET included in the semiconductor chip CP.

The gate pad PDG is electrically connected to a gate of the MOSFET included in the semiconductor chip CP. The gate pad PDG functions as a gate electrode of the MOSFET included in the semiconductor chip CP.

As illustrated in FIG. 3, a drain pad PDD is formed on the lower surface CPb of the semiconductor chip CP. The drain pad PDD is a metal film formed on the lower surface CPb of the semiconductor substrate provided in the semiconductor chip CP. The drain pad PDD is electrically connected to a drain of the MOSFET included in the semiconductor chip CP. The drain pad PDD functions as a drain electrode of the MOSFET included in the semiconductor chip CP.

As described above, various modifications are applicable to the semiconductor element included in the semiconductor chip CP. For example, in a modification using the semiconductor chip CP including an IGBT, in the above description of the MOSFET and the pads PD, a source is read as an emitter, and a drain is read as a collector.

As illustrated in FIG. 2, the plurality of leads LD of the semiconductor device PKG1 is arranged around the semiconductor chip CP. Each of the leads LD is made of, for example, copper or a copper alloy. In the example illustrated in FIG. 3, among the plurality of leads LD, a source lead LDS connected to the source pad PDS of the semiconductor chip CP extends to above the semiconductor chip CP. The source lead LDS is electrically connected to the source pad PDS via a conductive member CM1.

In addition, among the plurality of leads LD, a drain lead LDD is electrically connected to the drain pad PDD of the semiconductor chip CP via the copper plate MB1. More specifically, the drain lead LDD is electrically connected to the copper plate MB1 via a conductive member CM2.

Each of the conductive member CM1 and the conductive member CM2 is made of, for example, the same material as a bonding layer BL1. In this embodiment, each of the conductive member CM1 and the conductive member CM2 is a sintered silver layer (that is, a sintered layer containing silver as a main component). When each of the conductive member CM1, the conductive member CM2, and the bonding layer BL1 is formed of the same sintered silver layer, a heating process for sintering can be collectively performed.

In addition, among the plurality of leads LD, a gate lead LDG connected to the gate pad PDG of the semiconductor chip CP is electrically connected to the gate pad PDG via a wire (conductive member) BW. The wire BW is made of, for example, gold or copper.

For example, the plurality of leads LD is arranged around the semiconductor chip CP (in other words, around a die pad DP). Each of the leads LD is an external terminal having a function of electrically connecting the semiconductor device PKG1 to an external device (not illustrated). In the case of the semiconductor device PKG1, the plurality of leads LD is arranged along each side (each main side) of the sealing body MR having a quadrilateral planar shape.

In addition, as illustrated in FIG. 3, the semiconductor chip CP is bonded onto the copper plate MB1. More specifically, in this embodiment, a metal layer ML1 bonded to an upper surface MB1t of the copper plate MB1 and the bonding layer BL1 bonded to the metal layer ML1 are interposed between the semiconductor chip CP and the copper plate MB1.

The bonding layer BL1 is, for example, a sintered silver layer. Sintered silver has characteristics of high thermal conductivity and high heat resistance. In the case of a power semiconductor device such as that of this embodiment, heat is likely to be generated due to a large current flowing therethrough. Therefore, from a viewpoint of preventing malfunction of a circuit due to heat, it is preferable that heat dissipation performance or heat resistance is excellent. Accordingly, a sintered silver layer is suitable as the bonding layer BL1 included in the semiconductor device PKG1 of this embodiment.

When a sintered silver layer is used as the bonding layer BL1, from a viewpoint of improving connection reliability, a portion bonded to the sintered silver layer is preferably made of gold or silver. The sintered silver layer is formed, for example, as follows. First, a sintered silver paste is applied onto an underlying layer. The sintered silver paste is a paste material containing a large number of silver particles and a binder material made of an organic material. Next, the semiconductor chip CP is mounted on the sintered silver paste. Next, a lead frame on which the semiconductor chip CP is mounted is heated (fired) to sinter the plurality of silver particles. During the heating process, the binder material contained in the sintered silver paste volatilizes, thereby obtaining a sintered silver layer.

The sintered silver layer is a sintered layer containing silver as a main component. In other words, the weight percentage of silver is the highest among the elements contained in the sintered silver layer. However, the sintered silver layer is not limited to a layer made only of silver, and may contain elements other than silver.

When a member to be bonded to which the sintered silver layer is bonded is made of gold or silver, a part of silver particles is sintered to the member to be bonded. As a result, connection reliability at a bonding interface between the sintered silver layer and the member to be bonded can be improved.

For example, in the example illustrated in FIG. 3, the drain pad PDD bonded to an upper surface BL1t of the bonding layer BL1 is made of gold or silver. The metal layer ML1 bonded to a lower surface BL1b of the bonding layer BL1 is made of, for example, silver. More specifically, the metal layer ML1 is a silver plating layer.

As described above, the plurality of leads LD is made of, for example, copper or a copper alloy. However, at a bonding interface between the lead LD and the conductive member CM1 made of a sintered silver layer and at a bonding interface between the lead LD and the conductive member CM2 made of a sintered silver layer, a silver plating layer or a gold plating layer (not illustrated) is formed. Similarly, a metal layer ML2 is interposed between the conductive member CM2 and the copper plate MB1. The metal layer ML2 is made of silver. More specifically, similarly to the metal layer ML1, a silver plating layer is interposed in the metal layer ML2.

Note that each of the metal layer ML1 and the metal layer ML2 only needs to contain silver as a main component, and modes containing additive elements other than silver are not excluded.

### Separation Between Insulating Resin and Copper Plate

Next, separation between each of the copper plate MB1 and the copper plate MB2 and the sealing body MR illustrated in FIG. 3 will be described.

The sealing body MR plays a role of protecting components sealed inside the sealing body MR by being in close contact with the respective components. Therefore, it is necessary to suppress separation at adhesion interfaces between the sealing body MR and the respective components.

For example, in the semiconductor device PKG1 in FIG. 3, a part of the upper surface MB1t of the copper plate MB1 and a side surface MB1s thereof are in contact with the sealing body MR. In addition, a side surface MB2s of the copper plate MB2 is in contact with the sealing body MR.

When separation occurs at an adhesion interface between the upper surface MB1t of the copper plate MB1 and the sealing body MR and such separation progresses over a wide range, a positional relationship between the sealing body MR and the copper plate MB1 may be displaced. In particular, in the case of a power semiconductor device, since a temperature difference between an operating state and a non-operating state is large, expansion or contraction of the copper plate MB1 due to temperature changes may cause damage to the leads LD and the semiconductor chip CP connected to the copper plate MB1.

In addition, when separation occurs at an adhesion interface between the side surface MB2s of the copper plate MB2 and the sealing body MR illustrated in FIG. 3, moisture or the like may enter the interior of the semiconductor device PKG1 through a separated portion.

Since respective components constituting the semiconductor device PKG1 have different Young's moduli, stress may be generated due to differences in Young's modulus. For example, when the semiconductor chip CP (specifically, a semiconductor substrate of the semiconductor chip CP) is made of silicon carbide, a Young's modulus of silicon carbide is about several times higher than that of copper. In such portions where the difference in Young's modulus is large, stress (strain) caused by the difference in Young's modulus is generated. Separation between the sealing body MR and the respective components constituting the semiconductor device PKG1 occurs due to such stress.

However, even if separation occurs, the above-described problems are less likely to occur if progression of the separation can be suppressed.

Therefore, from a viewpoint of improving reliability of the semiconductor device PKG1, it is necessary to provide measures capable of suppressing occurrence of separation of the sealing body or progression of the separation even when the above-described stress is generated.

In addition, separation is more likely to occur at an adhesion interface between silver and the sealing body MR than at an adhesion interface between copper and the sealing body MR. In other words, adhesion strength between silver and the sealing body MR is lower than adhesion strength between copper and the sealing body MR. Therefore, in this embodiment in which a silver plating layer is used as the metal layer ML1, separation is likely to occur at a portion where the metal layer ML1 is in close contact with the sealing body MR.

In addition, when a temperature cycle load is applied to the semiconductor device PKG1, the above-described stress concentrates on a region where the semiconductor chip CP and the copper plate MB1 are bonded, and for example, cracks may be formed in the bonding layer BL1. Further, when separation occurs between the sealing body MR and the copper plate MB1 in a region around the semiconductor chip CP on the upper surface MB1t of the copper plate MB1, stress (strain) generated in the bonding layer BL1 increases, whereby cracks are likely to occur in the bonding layer BL1.

As illustrated in FIG. 3, the upper surface MB1t of the copper plate MB1, the side surface MB1s of the copper plate MB1, and the side surface MB2s of the copper plate MB2 are each roughened. As a method of roughening the surfaces of the copper plate MB1 and the copper plate MB2, examples include a method of roughening the surfaces by etching, a method of forming a roughened plating layer on the surfaces, and a method of irradiating the surfaces with a laser.

By roughening the surfaces of the copper plate MB1 and the copper plate MB2, an adhesion area with the sealing body MR increases as compared with a case where the surfaces are not roughened. Therefore, adhesion strength between each of the copper plate MB1 and the copper plate MB2 and the sealing body MR can be improved.

In addition, when the surfaces of the copper plate MB1 and the copper plate MB2 are roughened, the above-described stress is dispersed. In this case, even if separation occurs locally, progression of the separation can be suppressed.

Therefore, according to this embodiment, in the semiconductor device PKG1 in which a silver plating layer is used as the metal layer ML1, occurrence of separation or progression of separation can be suppressed.

In this embodiment, the copper plate MB1 and the semiconductor chip CP are electrically connected to each other. On the other hand, the copper plate MB1 and the copper plate MB2 are electrically separated from each other. The copper plate MB1 and the copper plate MB2 are located on opposite sides of each other with the insulating substrate SUB1 interposed therebetween. In this case, by roughening each of the upper surface MB1t of the copper plate MB1, the side surface MB1s of the copper plate MB1, and the side surface MB2s of the copper plate MB2, the following effects can be obtained.

From a viewpoint of electrically separating the copper plate MB1 and the copper plate MB2, it is preferable that each of the upper surface MB1t of the copper plate MB1, the side surface MB1s of the copper plate MB1, and the side surface MB2s of the copper plate MB2 is in close contact with the sealing body MR. In this manner, it is possible to prevent occurrence of creepage discharge along a peripheral region of the insulating substrate SUB1.

As illustrated in FIG. 2, the copper plate MB1 is bonded to a central region of the upper surface SBt (see FIG. 3) of the insulating substrate SUB1, the central region including a center of the upper surface SBt. In addition, the copper plate MB1 is not bonded to a peripheral region including an outer edge of the upper surface SBt of the insulating substrate SUB1.

Similarly, the copper plate MB2 illustrated in FIG. 3 is bonded to a central region of the lower surface SBb of the insulating substrate SUB1, the central region including a center of the lower surface SBb. In addition, the copper plate MB2 is not bonded to a peripheral region including an outer edge of the lower surface SBb of the insulating substrate SUB1.

When each of the copper plate MB1 and the copper plate MB2 is not bonded to the peripheral region as described above, a creepage distance between the copper plate MB1 and the copper plate MB2 can be increased. When the creepage distance is increased, occurrence of creepage discharge can be prevented.

In this embodiment, each of the upper surface MB1t of the copper plate MB1, the side surface MB1s of the copper plate MB1, and the side surface MB2s of the copper plate MB2 is roughened. Therefore, separation between each of the copper plate MB1 and the copper plate MB2 and the sealing body MR can be suppressed. Accordingly, even when the creepage distance between the copper plate MB1 and the copper plate MB2 is short, occurrence of creepage discharge can be prevented. In other words, in this embodiment, since creepage discharge can be prevented by the sealing body MR, an area of the peripheral region of the insulating substrate SUB1 can be reduced. As a result, a size of the semiconductor device PKG1 can be reduced.

Incidentally, as illustrated in FIG. 3, in this embodiment, the metal layer ML1 which is a silver plating layer is selectively formed on a part of the upper surface MB1t of the copper plate MB1. More specifically, the metal layer ML1 is selectively formed between the insulating substrate SUB1 and the semiconductor chip CP. Still more specifically, the metal layer ML1 is selectively formed between the copper plate MB1 and the semiconductor chip CP.

The structure illustrated in FIG. 3 can be expressed as follows. That is, the upper surface MB1t of the copper plate MB1 includes a region (chip mounting region) RCP in which the semiconductor chip CP is mounted via the metal layer ML1 which is a silver plating layer and a region RMR in which the metal layer ML1 is not formed. In the region RMR, the roughened upper surface MB1t of the copper plate MB1 and the sealing body MR are in close contact with each other.

As described above, separation is more likely to occur at an adhesion interface between silver and the sealing body MR than at an adhesion interface between copper and the sealing body MR. Therefore, from a viewpoint of preventing separation of the sealing body MR described above, it is preferable to reduce a range in which the sealing body MR and the metal layer ML1 made of silver are in contact with each other as much as possible.

In this embodiment, the metal layer ML1 made of silver is selectively formed between the semiconductor chip CP and the copper plate MB1. Accordingly, since a range in which the sealing body MR and the metal layer ML1 are in contact with each other can be reduced, occurrence of separation can be suppressed.

Although not illustrated, as a modification of this embodiment, the metal layer ML1 which is a silver plating layer may be formed over the entire upper surface MB1t of the copper plate MB1. In this modification, since an adhesion area between the silver plating layer and the sealing body MR is larger as compared with this embodiment, a possibility of occurrence of separation becomes higher. However, when unevenness is formed on an upper surface ML1t of the metal layer ML1 following a shape of the roughened upper surface MB1t of the copper plate MB1 as illustrated in FIG. 3, occurrence or progression of separation can be suppressed as compared with a case where the upper surface ML1t is flat. When the metal layer ML1 is a plating layer, a thickness of the metal layer ML1 can be reduced by controlling a plating time. By reducing the thickness of the metal layer ML1, unevenness following the upper surface MB1t is formed on the upper surface ML1t of the metal layer ML1 as illustrated in FIG. 3.

In addition, in the example illustrated in FIG. 3, a lower surface MB2b of the copper plate MB2 is exposed from the sealing body MR. In other words, the lower surface MB2b of the copper plate MB2 is not in contact with the sealing body MR. In this case, adhesion between the sealing body MR and the lower surface MB2b of the copper plate MB2 does not need to be taken into consideration. Therefore, the lower surface MB2b of the copper plate MB2 is not roughened. In this case, a surface roughness value of the lower surface MB2b of the copper plate MB2 is smaller than surface roughness values of the upper surface MB1t, the side surface MB1s, and the side surface MB2s.

### Degree of Roughening

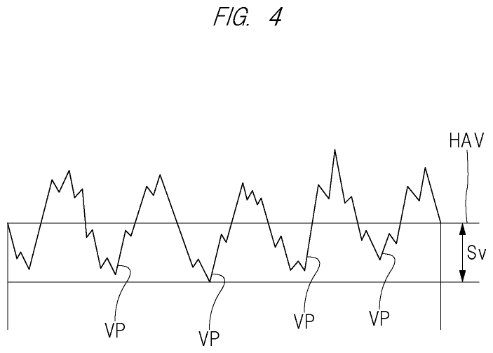

Next, a degree of roughening of the upper surface MB1t and the side surface MB1s of the copper plate MB1 and the side surface MB2s of the copper plate MB2 illustrated in FIG. 3 will be described. FIG. 4 is an explanatory diagram for describing a method of calculating a maximum valley depth (Sv), which is an evaluation index of surface roughness. In this embodiment, the degree of roughening is described using the maximum valley depth (Sv) as an evaluation index. The maximum valley depth Sv is defined as follows. First, an arbitrary region of a surface to be evaluated is set as a reference surface. Next, an average surface (average height) HAV of the reference surface having unevenness is measured. The shortest distance from a bottom of a recess having the largest distance from the average surface HAV among a plurality of recesses VP (that is, valleys) included in the reference surface to the average surface HAV is defined as the maximum valley depth Sv.

In the surfaces of the copper plate MB1 and the copper plate MB2 illustrated in FIG. 3, the maximum valley depth (Sv) of each of the roughened surfaces (the upper surface MB1t, the side surface MB1s, and the side surface MB2s) is preferably 2.0 μm or more and 3.0 μm or less.

As a result experimentally confirmed by the inventors of this application, when the maximum valley depth (Sv) is 2.0 μm or more, adhesion strength between the copper plate MB1 and the sealing body MR becomes twice or more as large as that in a case where roughening process is not performed. For example, when roughening process is not performed, adhesion strength between the copper plate MB1 and the sealing body MR is approximately 10 MPa. When roughening process is performed to have the maximum valley depth (Sv) of 2.0 μm, adhesion strength between the copper plate MB1 and the sealing body MR is 20 MPa or more.

In addition, when the maximum valley depth (Sv) is larger than 3.0 μm, roughening process may require a long time. Further, separation of the sealing body MR can be sufficiently prevented when the maximum valley depth (Sv) is 2.0 μm or more and 3.0 μm or less. Therefore, it is particularly preferable that the maximum valley depth (Sv) of each surface obtained by roughening process is 2.0 μm or more and 3.0 μm or less.

### First Modification

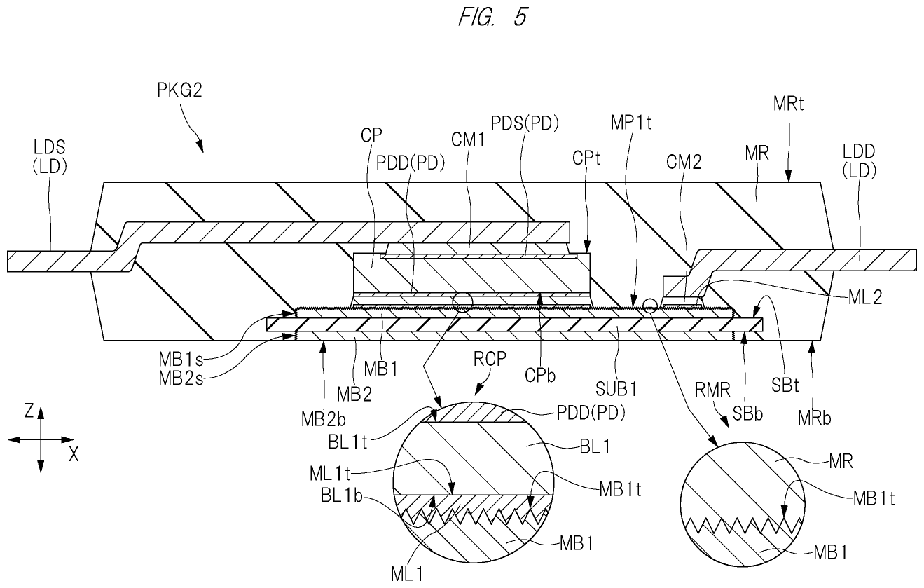

Some modifications will be described below. FIG. 5 is a cross-sectional view illustrating a modification of the semiconductor device illustrated in FIG. 3.

A semiconductor device PKG2 illustrated in FIG. 5 differs from the semiconductor device PKG1 illustrated in FIG. 3 in the following points. The bonding layer BL1 included in the semiconductor device PKG2 is made of solder. Even when solder is used as the bonding layer BL1, the metal layer ML1 made of a silver plating layer may be interposed between the copper plate MB1 and the bonding layer BL1.

For example, in recent years, in response to requirements of regulations such as the RoHS (Restriction on Hazardous Substances) directive, lead-free solder materials have been promoted. When lead solder which is an alloy of tin and lead is replaced with lead-free solder, it may be preferable to bond the solder via the metal layer ML1 which is a silver plating layer than to directly bond the solder to the copper plate MB1 illustrated in FIG. 3. Lead-free solder may have inferior wettability as compared with lead solder. When a silver plating layer is provided as an underlying layer for lead-free solder, wettability of the lead-free solder can be improved as compared with a case where lead-free solder is directly bonded to the copper plate MB1.

When lead is used as the bonding layer BL1, for example, the bonding layer BL1 is formed as follows. First, a solder paste is applied to an underlying layer. The solder paste is a paste material containing metal element components constituting solder and a binder material made of an organic material. Next, the semiconductor chip CP is mounted on the solder paste. Next, a lead frame on which the semiconductor chip CP is mounted is heated and then cooled. This process is referred to as a reflow process. By performing the reflow process, solder components are alloyed, thereby obtaining the bonding layer BL1 made of solder. The binder material contained in the solder paste volatilizes during the reflow process.

Here, when solder is used as the bonding layer BL1, the following problems may arise if the surface of the underlying layer on which the solder paste is applied is roughened. For example, when the solder paste is subjected to reflow process, solder components spread by wetting along the underlying layer. At this time, if the underlying layer has unevenness, wetting of the solder may become locally insufficient due to being hindered by the unevenness of the underlying layer.

On the other hand, in order to facilitate spreading by wetting of solder, there is a method of performing reflow in a formic acid atmosphere for the purpose of improving surface activity of solder components. In this case, conversely, the solder may excessively spread by wetting. When the solder excessively spreads by wetting, the solder spreads even to a periphery of the bonding layer BL1, and as a result, a thickness of the bonding layer BL1 may become insufficient.

In consideration of the above-described problems, in this modification in which solder is used as the bonding layer BL1, it is preferable that the upper surface ML1t of the metal layer ML1 which is an underlying layer of the bonding layer BL1 is flatter than the upper surface MB1t of the copper plate MB1.

As described above with reference to FIG. 3, when a thickness of the metal layer ML1 is small, a shape of the upper surface ML1t of the metal layer ML1 becomes an uneven shape following a shape of the roughened upper surface MB1t of the copper plate MB1.

As illustrated in FIG. 5, when a thickness of the metal layer ML1 is large enough to fill entire recesses of the roughened upper surface MB1t, the upper surface ML1t of the metal layer ML1 can be planarized.

In addition, as already described with reference to FIG. 3, from a viewpoint of simplifying manufacturing process, it is preferable that each of the bonding layer BL1, the conductive member CM1, and the conductive member CM2 illustrated in FIG. 5 is made of the same material. In this modification, since the bonding layer BL1 is made of solder, it is preferable that each of the conductive member CM1 and the conductive member CM2 is similarly made of solder.

Except for the above-described differences, the semiconductor device PKG2 illustrated in FIG. 5 is the same as the semiconductor device PKG1 described with reference to FIG. 3. Therefore, redundant description is omitted.

### Second Modification

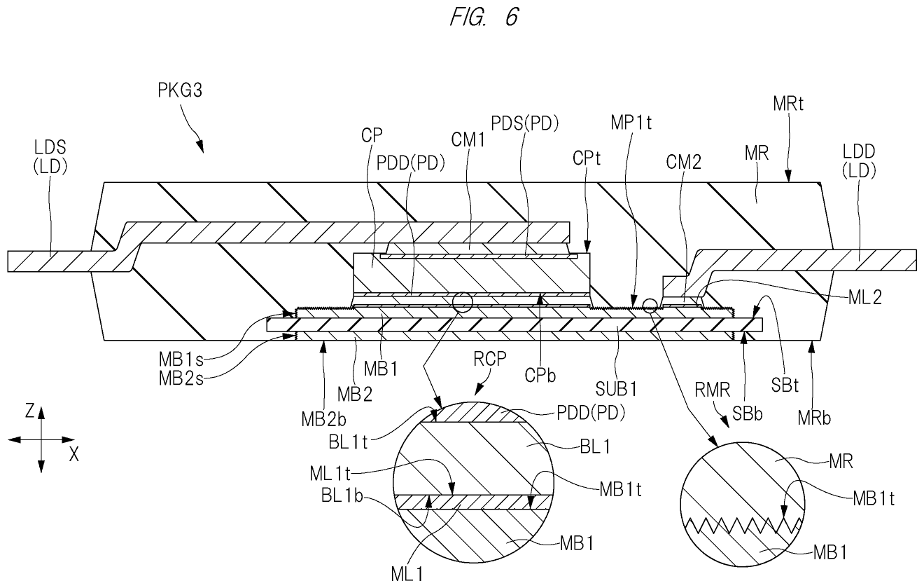

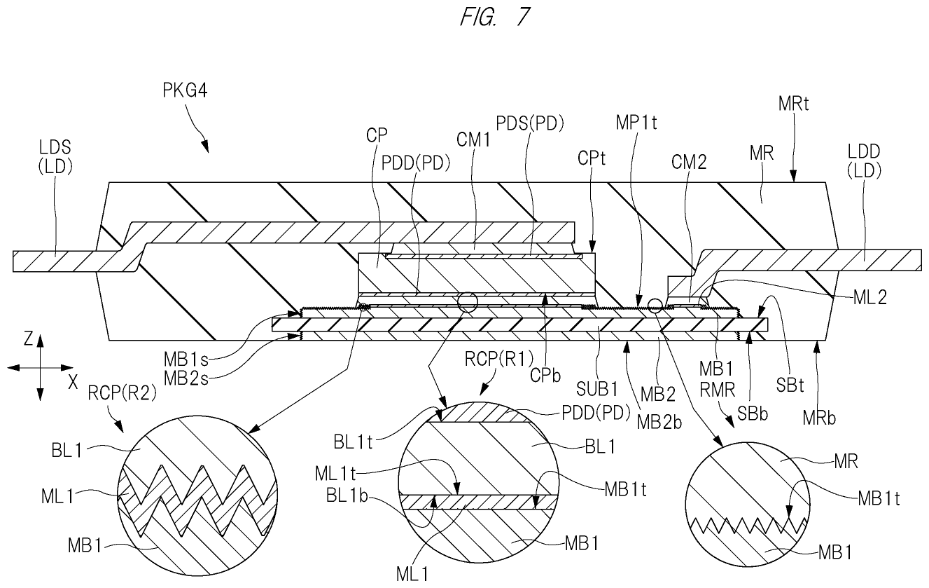

FIG. 6 is a cross-sectional view illustrating a modification of the semiconductor device illustrated in FIG. 5. FIG. 7 is a cross-sectional view illustrating a modification of the semiconductor device illustrated in FIG. 6.

A semiconductor device PKG3 illustrated in FIG. 6 differs from the semiconductor device PKG2 illustrated in FIG. 5 in that surface roughness of the region RMR not overlapping with the semiconductor chip is greater than surface roughness of the region RCP overlapping with the semiconductor chip CP. In other words, in this modification, surface roughness of the region RCP covered with the metal layer ML1 which is a silver plating layer is flatter than surface roughness of the region RMR in which the sealing body MR and the copper plate MB1 are in close contact with each other.

As described above, when solder is used as the bonding layer BL1, it is preferable that the upper surface ML1t of the metal layer ML1 which is an underlying layer of the bonding layer BL1 is flat. In this modification, on the upper surface MB1t of the copper plate MB1, a region in contact with the metal layer ML1 is not roughened. As a result, the upper surface ML1t can be easily planarized without increasing a thickness of the metal layer ML1.

Note that this modification has been described as a modification of the semiconductor device PKG2 illustrated in FIG. 5. However, a mode in which, on the upper surface MB1t of the copper plate MB1, the region RCP overlapping with the semiconductor chip CP is not roughened as in this modification can also be combined with the semiconductor device PKG1 described with reference to FIG. 3. In this case, a sintered silver layer is used as each of the bonding layer BL1, the conductive member CM1, and the conductive member CM2 illustrated in FIG. 6 instead of solder.

Except for the above-described differences, the semiconductor device PKG3 illustrated in FIG. 6 is the same as the semiconductor device PKG2 described with reference to FIG. 5. Therefore, redundant description is omitted.

### Third Modification

FIG. 7 is a cross-sectional view illustrating a modification of the semiconductor device illustrated in FIG. 6.

A semiconductor device PKG4 illustrated in FIG. 7 differs from the semiconductor device PKG3 illustrated in FIG. 6 in the following points. That is, the region RCP of the upper surface MB1t of the copper plate MB1 included in the semiconductor device PKG4 includes a region R1 and a region R2. The region R1 is a region that is flatter than surface roughness of the region RMR. On the other hand, the region R2 is arranged so as to surround the region R1, and the region R2 is rougher than surface roughness of a region R3.

The semiconductor device PKG3 illustrated in FIG. 6 and the semiconductor device PKG4 illustrated in FIG. 7 differ from the semiconductor device PKG1 illustrated in FIG. 3 and the semiconductor device PKG2 illustrated in FIG. 5 in that the upper surface MB1t of the copper plate MB1 includes a region that is not roughened. In this modification, it is difficult to form the metal layer ML1 which is a silver plating layer only on the region that is not roughened due to manufacturing tolerances.

In the case of the semiconductor device PKG4 illustrated in FIG. 7, the region R1 in which the upper surface MB1t of the copper plate MB1 and the upper surface ML1t of the metal layer ML1 are not roughened is surrounded by the region R2. Therefore, even when manufacturing tolerances in manufacturing process are taken into consideration, it is possible to prevent the region in which the upper surface MB1t of the copper plate MB1 and the upper surface ML1t of the metal layer ML1 are not roughened from coming into contact with the sealing body MR.

In other words, in this modification, even when manufacturing tolerances in manufacturing process are taken into consideration, separation between the sealing body MR and the copper plate MB1 can be prevented.

Note that this modification has been described as a modification of the semiconductor device PKG3 illustrated in FIG. 6. However, this modification can also be combined with the semiconductor device PKG1 described with reference to FIG. 3. In this case, a sintered silver layer is used as each of the bonding layer BL1, the conductive member CM1, and the conductive member CM2 illustrated in FIG. 7 instead of solder.

Except for the above-described differences, the semiconductor device PKG4 illustrated in FIG. 7 is the same as the semiconductor device PKG3 described with reference to FIG. 6. Therefore, redundant description is omitted.

### Fourth Modification

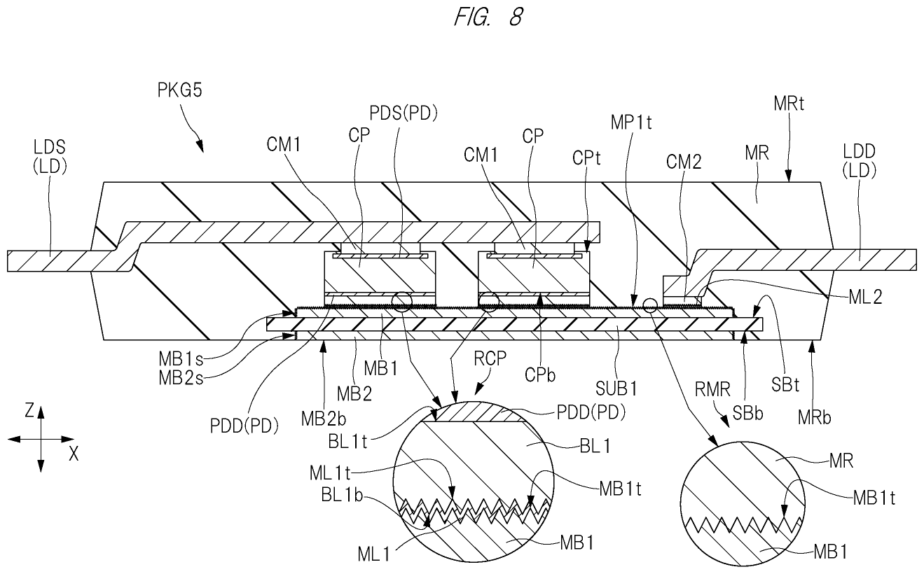

FIG. 8 is a cross-sectional view illustrating another modification of the semiconductor device illustrated in FIG. 1.

A semiconductor device PKG5 illustrated in FIG. 8 differs from the semiconductor device PKG1 illustrated in FIG. 3 in that the semiconductor device PKG5 includes a plurality of semiconductor chips CP. The leads LD are arranged around the plurality of semiconductor chips CP. Each of the semiconductor chips CP is electrically connected to the leads LD via the conductive member CM1 and the conductive member CM2. In the example illustrated in FIG. 8, the source pad PDS of each of the semiconductor chips CP is electrically connected to the source lead LDS via the conductive member CM1. The drain pad PDD of each of the semiconductor chips CP is electrically connected to the drain lead LDD via the conductive member CM2.

In addition, in this modification, the upper surface MB1t of the copper plate MB1 includes a plurality of regions RCP spaced apart from each other. The plurality of regions RCP is surrounded by the region RMR that is in contact with the sealing body MR.

In FIG. 8, the semiconductor device PKG5 is illustrated as an example of a modular semiconductor device in which the plurality of semiconductor chips CP is electrically connected to each other. However, the number of semiconductor chips CP or a method of electrically connecting the semiconductor chips CP is not limited to the mode illustrated in FIG. 1, and various modifications may be applied.

Further, this modification has been described as a modification of the semiconductor device PKG1 illustrated in FIG. 1. However, this modification can also be combined with the respective modifications described with reference to FIG. 3 to FIG. 7.

Except for the above-described differences, the semiconductor device PKG5 illustrated in FIG. 8 is the same as the semiconductor device PKG1 described with reference to FIG. 3. Therefore, redundant description is omitted.

### Fifth Modification

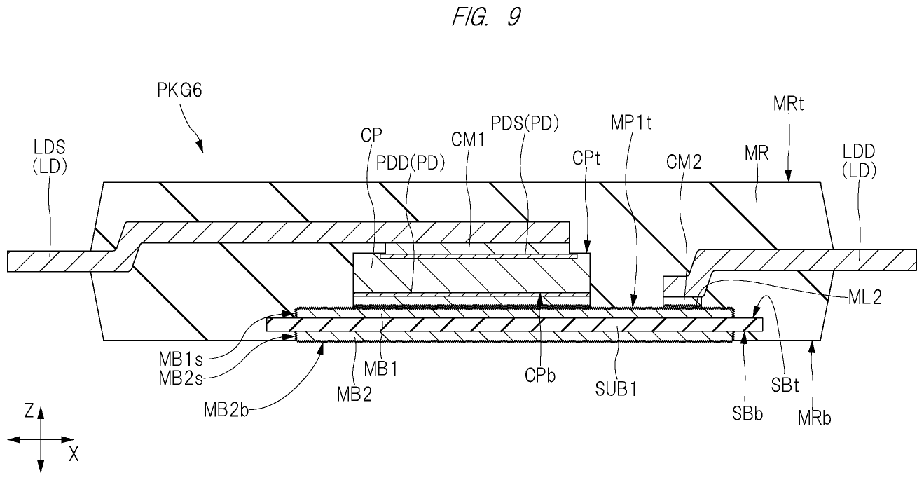

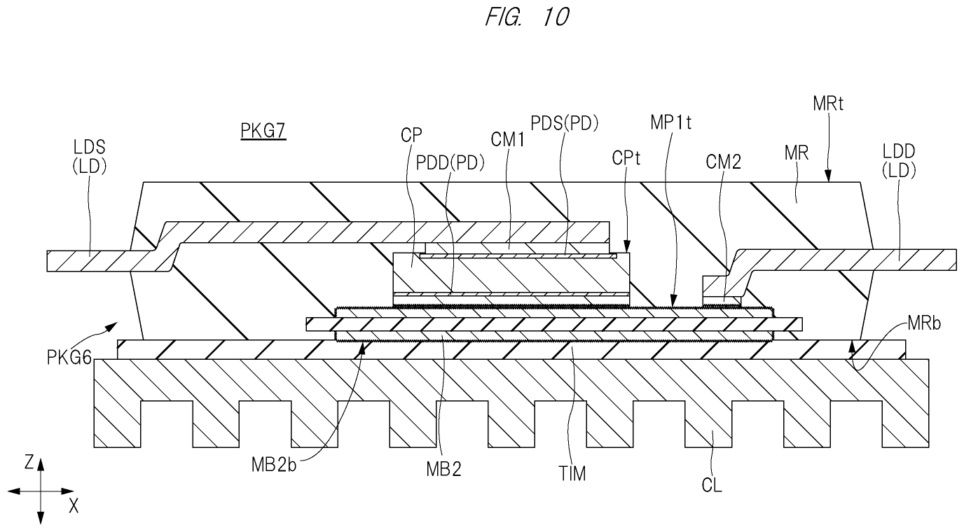

FIG. 9 is a cross-sectional view illustrating another modification of the semiconductor device illustrated in FIG. 1. FIG. 10 is a cross-sectional view illustrating a state in which a cooler is connected to a lower surface of the semiconductor device illustrated in FIG. 9.

A semiconductor device PKG6 illustrated in FIG. 9 differs from the semiconductor device PKG1 illustrated in FIG. 3 in that the lower surface MB2b of the copper plate MB2 is roughened. A semiconductor device PKG7 illustrated in FIG. 10 further includes a cooler CL bonded to the lower surface MB2b of the copper plate MB2 via a resin sheet TIM.

As already described with reference to FIG. 3, the lower surface MB2b of the copper plate MB2 is not exposed from the sealing body MR. Therefore, the lower surface MB2b and the sealing body MR are not in contact with each other. In this case, as illustrated in FIG. 3, there is no influence on separation of the sealing body MR even when the lower surface MB2b is not roughened.

However, when the lower surface MB2b is roughened as in this modification, it may be advantageous in a case where another member is connected to the lower surface MB2b.

As described above, since a large current flows through a power semiconductor device, a large amount of heat is generated. Therefore, by adopting a structure in which the lower surface MB2b of the copper plate MB2 is exposed from the sealing body MR and the copper plate MB2 is thermally connected to the cooler CL as in the semiconductor device PKG7 illustrated in FIG. 10, heat dissipation efficiency can be improved.

For example, in the case of the semiconductor device PKG7 illustrated in FIG. 10, the resin sheet TIM is in close contact with the lower surface MB2b of the copper plate MB2. The resin sheet TIM is a member constituting a heat dissipation path from the semiconductor device PKG6 to the cooler CL. Therefore, from a viewpoint of improving heat dissipation efficiency from the semiconductor device PKG6 to the cooler CL, it is preferable that the lower surface MB2b of the copper plate MB2 and the resin sheet TIM are in close contact over a wide range.

In this modification, since the lower surface MB2b of the copper plate MB2 is roughened, separation between the lower surface MB2b of the copper plate MB2 and the resin sheet TIM can be suppressed.

In FIG. 9 and FIG. 10, a modification of the semiconductor device PKG1 illustrated in FIG. 3 is illustrated as an example of a semiconductor device in which the lower surface MB2b of the copper plate MB2 is roughened. However, this modification can also be combined with the respective modifications described with reference to FIG. 3 to FIG. 8.

In the example illustrated in FIG. 10, the cooler CL is a so-called heat dissipation fin. However, various modifications may be applied as the cooler CL.

Except for the above-described differences, the semiconductor device PKG6 illustrated in FIG. 9 and FIG. 10 is the same as the semiconductor device PKG1 described with reference to FIG. 3. Therefore, redundant description is omitted.

### Method of Manufacturing Semiconductor Device

Next, a method of manufacturing a semiconductor device will be described. In this section, as a representative example, a method of manufacturing the semiconductor device PKG1 described with reference to FIG. 1 to FIG. 3 will be described. With respect to the respective modifications, several variations will be described regarding a roughening method of copper plate and a timing of forming a silver plating layer.

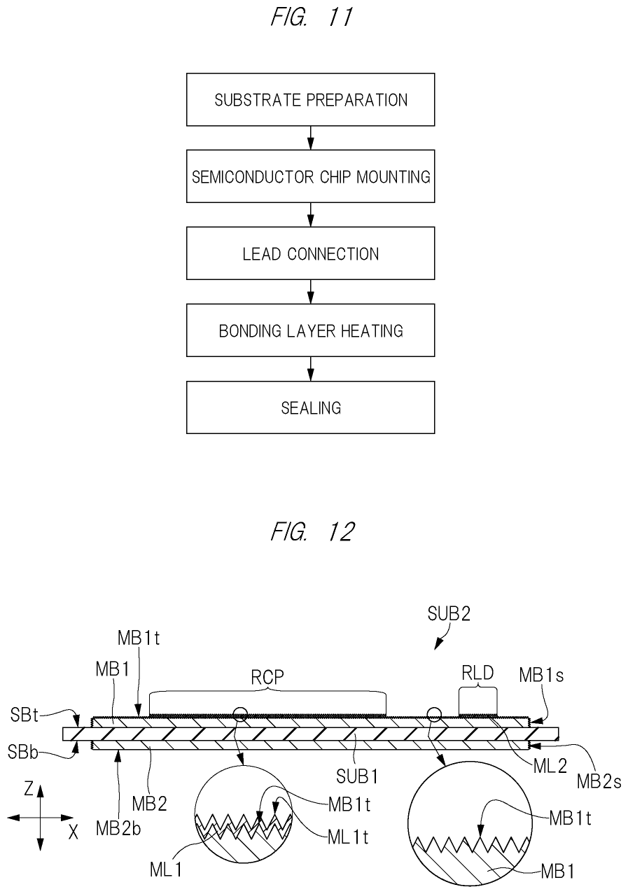

FIG. 11 is an explanatory diagram illustrating an example of a flow of a manufacturing process of a semiconductor device according to one embodiment. As illustrated in FIG. 11, the method of manufacturing the semiconductor device according to one embodiment includes a substrate preparation step, a semiconductor chip mounting step, a lead connection step, a bonding layer heating step, and a sealing step.

In the substrate preparation step illustrated in FIG. 11, for example, a substrate SUB2 illustrated in FIG. 12 is prepared. FIG. 12 is a cross-sectional view illustrating an example of a substrate prepared in the substrate preparation step illustrated in FIG. 11. The substrate SUB2 includes the insulating substrate SUB1, the copper plate MB1 bonded to the upper surface SBt of the insulating substrate SUB1, and the copper plate MB2 bonded to the lower surface SBb of the insulating substrate SUB1.

In the substrate SUB2 prepared in this step, each of the upper surface MB1t of the copper plate MB1, the side surface MB1s of the copper plate MB1, and the side surface MB2s of the copper plate MB2 is roughened. In addition, on the upper surface MB1t of the copper plate MB1, the metal layer ML1 which is a silver plating layer is formed in advance in the region (chip mounting region) RCP on which the semiconductor chip CP (see FIG. 3) is mounted in the semiconductor chip mounting step.

In addition, in the example illustrated in FIG. 12, on the upper surface MB1t of the copper plate MB1, the metal layer ML2 is disposed in a region (lead connection region) RLD to which a part of the lead LD is electrically connected in the lead connection step. The metal layer ML2 is a silver plating layer similarly to the metal layer ML1 formed in the region RCP.

The above-mentioned roughening method and the method of selectively forming the metal layer ML1 and the metal layer ML2 will be described later.

In the semiconductor chip mounting step, as described with reference to FIG. 3, at least one semiconductor chip CP is mounted on the copper plate MB1 via the metal layer ML1 and the bonding layer BL1. In this step, the semiconductor chip CP is mounted on a paste-like bonding layer.

For example, when sintered silver is used as the bonding layer BL1 as in the example illustrated in FIG. 3, the step is as follows. First, a sintered silver paste is applied to the metal layer ML1 which is an underlying layer. The sintered silver paste is a paste material containing a large number of silver particles and a binder material made of an organic material. Next, the semiconductor chip CP is mounted on the sintered silver paste.

The sintered silver paste is heated (fired) in the bonding material heating step illustrated in FIG. 11. As a result, the plurality of silver particles is sintered, thereby obtaining the bonding layer BL1 which is a sintered silver layer. The binder material contained in the sintered silver paste volatilizes during heating. In addition, a part of the silver particles is sintered to the metal layer ML1 which is an underlying layer.

Alternatively, when solder is used as the bonding layer BL1 as in the example illustrated in FIG. 5, the step is as follows. First, a solder paste is applied to the metal layer ML1 which is an underlying layer. The solder paste is a paste material containing metal element components constituting solder and a binder material made of an organic material. Next, the semiconductor chip CP is mounted on the solder paste.

The solder paste is heated (reflowed) in the bonding material heating step illustrated in FIG. 11. As a result, solder components are alloyed, thereby obtaining the bonding layer BL1 made of solder. The binder material contained in the solder paste volatilizes during the reflow process.

In this embodiment, sintered silver paste or solder paste is used as the bonding layer at a plurality of locations. From a viewpoint of improving manufacturing efficiency, it is preferable that the paste materials at the plurality of locations are collectively subjected to a heating process. Therefore, at the stage of this step, for example, the bonding layer BL1 remains in a paste state, and the process proceeds to a subsequent step.

In the lead connection step illustrated in FIG. 11, each of the leads LD illustrated in FIG. 3 is connected to the semiconductor chip CP or the copper plate MB1. In the example illustrated in FIG. 3, among the plurality of leads LD, the source lead LDS is connected to the source pad PDS via the conductive member CM1. Among the plurality of leads LD, the drain lead LDD is connected to the drain pad PDD via the metal layer ML2 and the conductive member CM2. In addition, the gate pad PDG illustrated in FIG. 2 is connected to the gate lead LDG via the wire BW.

As already described, each of the conductive member CM1 and the conductive member CM2 illustrated in FIG. 3 is made of the same material as the bonding layer BL1. Therefore, details of a connection method in this step are the same as those in the semiconductor chip mounting step described above. Accordingly, redundant description is omitted.

In the bonding layer heating step illustrated in FIG. 11, a sintered silver layer is obtained by firing the sintered silver paste. Alternatively, a solder layer is obtained by reflowing the solder paste.

In the sealing step illustrated in FIG. 11, as illustrated in FIG. 3, the semiconductor chip CP and the insulating substrate are sealed with an insulating resin. As a method of forming the sealing body MR, examples include a method in which a lead frame is placed in a molding die for resin molding and then an insulating resin is injected into the molding die. The insulating resin contains a thermosetting resin component, and after being molded in the molding die, the thermosetting resin component is cured by heating. Such a molding method is referred to as a transfer molding method.

In this embodiment, for example, as described with reference to FIG. 3, it is necessary to form the sealing body MR so as to cover the side surface MB2s of the copper plate MB2 and expose the lower surface MB2b of the copper plate MB2. In this case, the transfer molding method is effective.

### Details of Substrate Preparation Step

Next, details of the substrate preparation step illustrated in FIG. 11 will be described. In the following description, respective steps of the substrate preparation step will be described sequentially with reference to schematic cross-sectional views illustrating the substrate SUB2 illustrated in FIG. 12. Each drawing used in the following description is a cross-sectional view and illustrates a portion corresponding to the region RCP illustrated in FIG. 12.

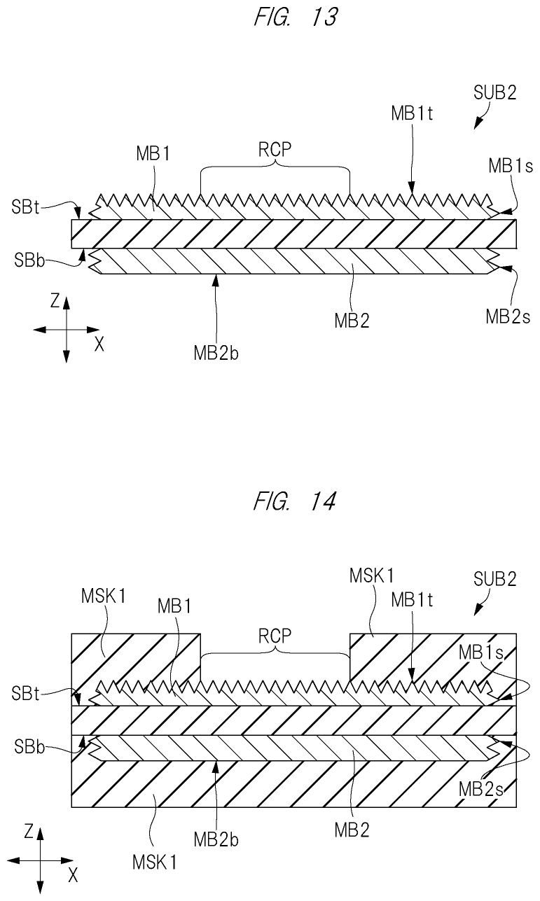

The substrate preparation step illustrated in FIG. 11 includes, for example, the following steps. FIG. 13 is a cross-sectional view illustrating a state in which surfaces of copper plates bonded to an insulating substrate are roughened in the substrate preparation step illustrated in FIG. 11.

In the example illustrated in FIG. 13, the substrate preparation step includes a roughening step. In the roughening step, the upper surface MB1t of the copper plate MB1, the side surface MB1s of the copper plate MB1, and the side surface MB2s of the copper plate MB2 are each roughened. As already described, examples of a method of roughening the surfaces of the copper plates MB1 and MB2 include a method of roughening the surfaces by etching, a method of forming a roughened plating layer on the surfaces, and a method of irradiating the surfaces with a laser.

FIG. 14 is a cross-sectional view illustrating a state in which a mask is formed such that a chip mounting region of the copper plate illustrated in FIG. 13 is exposed in the substrate preparation step illustrated in FIG. 11.

In the example illustrated in FIG. 14, the substrate preparation step includes a plating mask forming step. In the plating mask forming step, after the roughening step described with reference to FIG. 13, a mask MSK1 is formed such that the region RCP is exposed.

In this step, the mask MSK1 is formed so as to cover a part of the upper surface MB1t of the copper plate MB1 (portions other than the region RCP), the side surface MB1s of the copper plate MB1, and the side surface MB2s of the copper plate MB2.

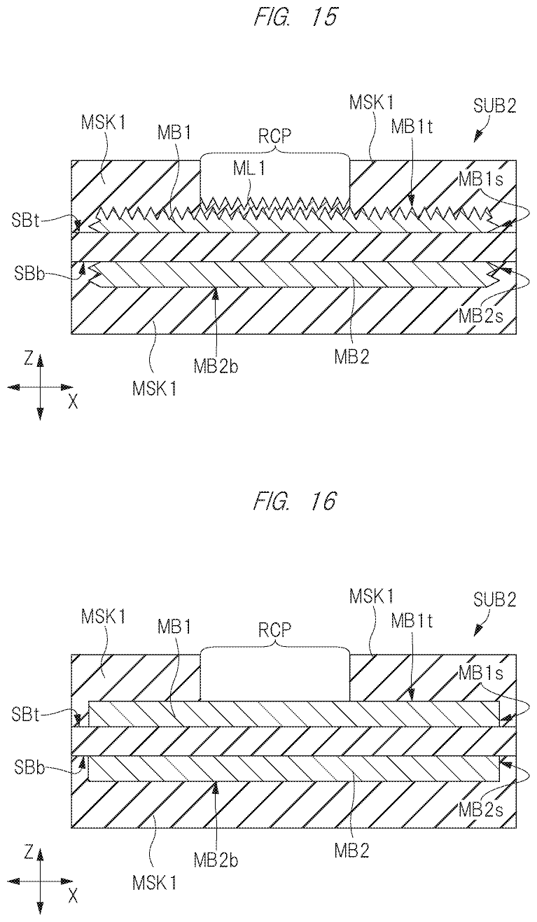

FIG. 15 is a cross-sectional view illustrating a state in which a silver plating layer is selectively formed in the chip mounting region of the copper plate illustrated in FIG. 14 in the substrate preparation step illustrated in FIG. 11.

In the example illustrated in FIG. 15, the substrate preparation step includes a plating step. In the plating step, after the plating mask forming step described with reference to FIG. 14, the metal layer ML1 is selectively formed in the region RCP.

As already described, the thickness of the metal layer ML1 can be controlled by controlling a plating time in this step.

### First Modification of Substrate Preparation Step

Next, a modification of the substrate preparation step illustrated in FIG. 11 will be described. In this modification, the substrate preparation step illustrated in FIG. 11 includes, for example, the following steps. FIG. 16 is a cross-sectional view illustrating a state in which a mask is formed such that a chip mounting region of a copper plate bonded to an upper surface of an insulating substrate is exposed in the substrate preparation step illustrated in FIG. 11.

In the example illustrated in FIG. 16, the substrate preparation step includes a plating mask forming step. In the plating mask forming step, the mask MSK1 is formed such that the region RCP of the upper surface MB1t of the copper plate MB1, which is not subjected to roughening process, is exposed.

In this step, the mask MSK1 is formed so as to cover a part of the upper surface MB1t of the copper plate MB1 (portions other than the region RCP), the side surface MB1s of the copper plate MB1, and the side surface MB2s of the copper plate MB2.

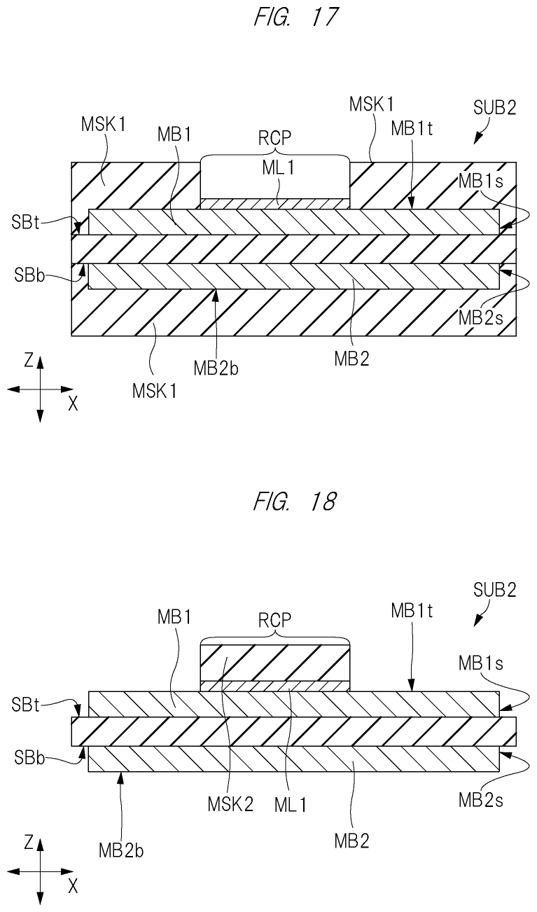

FIG. 17 is a cross-sectional view illustrating a state in which a silver plating layer is selectively formed in the chip mounting region of the copper plate illustrated in FIG. 16 in the substrate preparation step illustrated in FIG. 11.

In the example illustrated in FIG. 17, the substrate preparation step includes a plating step. In the plating step, after the plating mask forming step described with reference to FIG. 16, the metal layer ML1 is selectively formed in the region RCP.

In this modification, the metal layer ML1 which is a silver plating layer is formed on the copper plate MB1 that is not roughened. Therefore, regardless of the thickness of the metal layer ML1, the upper surface of the metal layer ML1 is a flat surface.

FIG. 18 is a cross-sectional view illustrating a state in which a mask is selectively formed so as to cover the silver plating layer in the chip mounting region illustrated in FIG. 17 in the substrate preparation step illustrated in FIG. 11.

In the example illustrated in FIG. 18, the substrate preparation step includes a roughening mask forming step. In the roughening mask forming step, after the plating step described with reference to FIG. 17, a mask MSK2 that selectively covers the metal layer ML1 is formed.

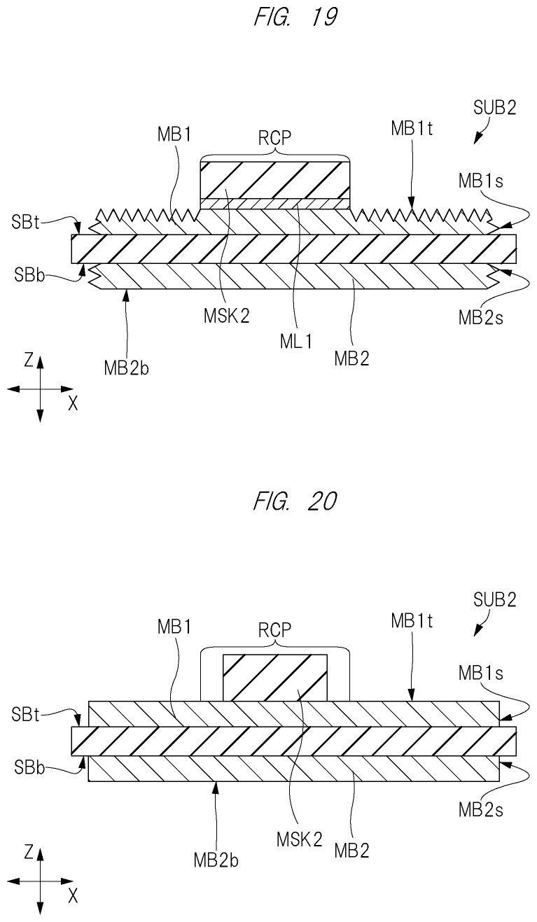

FIG. 19 is a cross-sectional view illustrating a state in which surfaces of copper plates are roughened while the silver plating layer is covered with the mask in the substrate preparation step illustrated in FIG. 11.

In the example illustrated in FIG. 19, the substrate preparation step includes a roughening step. In the roughening step, while the metal layer ML1 is covered with the mask MSK2, the upper surface MB1t of the copper plate MB1, the side surface MB1s of the copper plate MB1, and the side surface MB2s of the copper plate MB2 are each roughened. Since the roughening method has already been described, redundant description is omitted.

After the roughening step, by removing the mask MSK2 illustrated in FIG. 19, the substrate SUB2 (see FIG. 19) that can be applied to the semiconductor device PKG3 described with reference to FIG. 6 can be formed.

### Second Modification of Substrate Preparation Step

Next, another modification of the substrate preparation step illustrated in FIG. 11 will be described. In this modification, the substrate preparation step illustrated in FIG. 11 includes, for example, the following steps. FIG. 20 is a cross-sectional view illustrating a state in which a mask is formed so as to selectively cover a chip mounting region of a copper plate bonded to an upper surface of an insulating substrate in the substrate preparation step illustrated in FIG. 11.

In the example illustrated in FIG. 20, the substrate preparation step includes a roughening mask forming step. In the roughening mask forming step, the mask MSK2 is formed so as to selectively cover the region RCP which is a chip mounting region. In this step, it is preferable that the entire region RCP is covered with the mask MSK2 and regions other than the region RCP are exposed from the mask MSK2. However, in consideration of tolerances in forming the mask MSK2, positional deviation may occur between an outer edge of the region RCP and an edge of the mask MSK2.

In this step, when a region outside the region RCP is covered with the mask MSK2, a region of the upper surface MB1t of the copper plate MB1 that is not roughened may come into contact with the sealing body MR (see FIG. 3). Therefore, from a viewpoint of ensuring that the region that comes into contact with the sealing body MR is reliably roughened, the mode illustrated in FIG. 20 is preferable in this step. That is, in the region RCP which is a chip mounting region, a portion including a center thereof (in other words, a central portion) is covered with the mask MSK2, and a peripheral portion thereof is exposed from the mask MSK2.

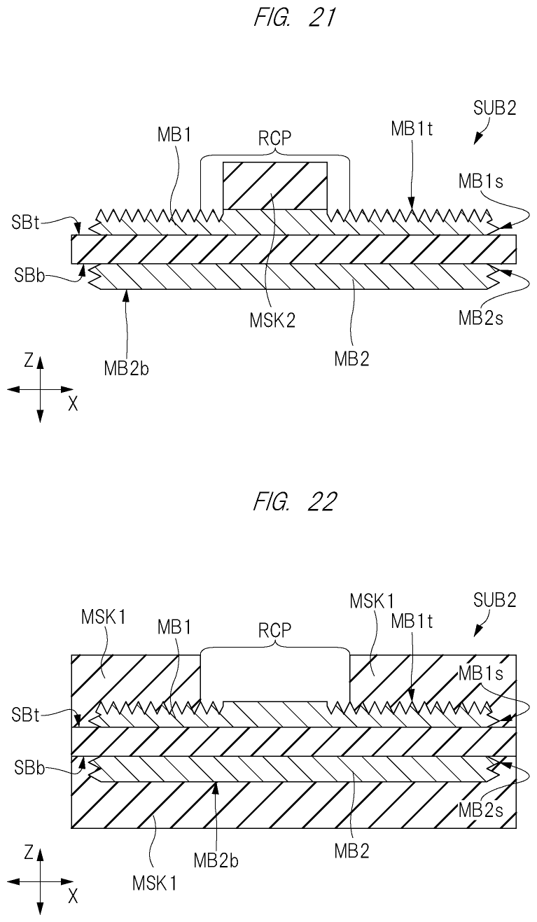

FIG. 21 is a cross-sectional view illustrating a state in which surfaces of the copper plates are roughened while the chip mounting is covered with the mask in the substrate preparation step illustrated in FIG. 11.

In the example illustrated in FIG. 21, the substrate preparation step includes a roughening step. In the roughening step, while the region RCP which is a chip mounting region is covered with the mask MSK2, the upper surface MB1t of the copper plate MB1, the side surface MB1s of the copper plate MB1, and the side surface MB2s of the copper plate MB2 are each roughened. More specifically, portions of the upper surface MB1t of the copper plate MB1 exposed from the mask MSK2 are roughened. Therefore, in this modification, a peripheral portion of the region RCP is also roughened. Since the roughening method has already been described, redundant description is omitted.

FIG. 22 is a cross-sectional view illustrating a state in which the roughening mask illustrated in FIG. 21 is removed, and a plating mask is then formed such that the chip mounting region is exposed in the substrate preparation step illustrated in FIG. 11.

In the example illustrated in FIG. 22, the substrate preparation step includes a plating mask forming step. In the plating mask forming step, after removing the roughening mask MSK2 (see FIG. 21), the mask MSK1 is formed such that the upper surface MB1t of the copper plate MB1 in the region RCP is exposed.

In this step, the mask MSK1 is formed so as to cover a part of the upper surface MB1t of the copper plate MB1 (portions other than the region RCP), the side surface MB1s of the copper plate MB1, and the side surface MB2s of the copper plate MB2.

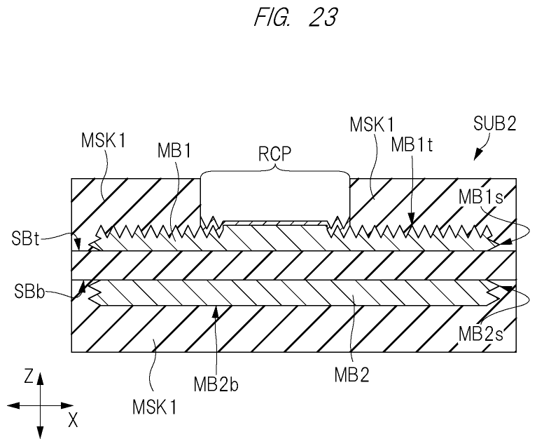

FIG. 23 is a cross-sectional view illustrating a state in which a silver plating layer is selectively formed in the chip mounting region of the copper plate illustrated in FIG. 22 in the substrate preparation step illustrated in FIG. 11.

In the example illustrated in FIG. 23, the substrate preparation step includes a plating step. In the plating step, after the plating mask forming step described with reference to FIG. 22, the metal layer ML1 is selectively formed in the region RCP.

In this modification, in the roughening step, the central portion of the region RCP is not roughened, and the peripheral portion of the region RCP is roughened. Therefore, in the plating step, the metal layer ML1 is formed so as to extend across a non-roughened region and a part of a roughened region of the upper surface MB1t of the copper plate MB1.

After the plating step, by removing the mask MSK1 illustrated in FIG. 23, the substrate SUB2 (see FIG. 23) that can be applied to the semiconductor device PKG4 described with reference to FIG. 7 can be formed.

In the foregoing, the invention made by the inventors of this application has been specifically described based on the embodiments, but the present invention is not limited to the embodiments above, and it goes without saying that various modifications can be made within the range not departing from the gist of the invention.

What is claimed is:

1. A semiconductor device comprising:
an insulating substrate;
a first copper plate made of copper or a copper alloy and bonded to an upper surface of the insulating substrate;
a second copper plate made of copper or a copper alloy and bonded to a lower surface of the insulating substrate;
at least one semiconductor chip bonded to the first copper plate via a first metal layer made of silver; and
an insulating resin formed to seal the semiconductor chip and the insulating substrate,
wherein an upper surface of the first copper plate, a side surface of the first copper plate, and a side surface of the second copper plate are each roughened.

2. The semiconductor device according to claim 1, further comprising a first bonding layer between the first metal layer and the semiconductor chip.

3. The semiconductor device according to claim 2,
wherein the first bonding layer is a sintered metal layer containing silver as a main component.

4. The semiconductor device according to claim 2,
wherein the first bonding layer is made of solder.

5. The semiconductor device according to claim 1,
wherein the first metal layer is selectively formed between the insulating substrate and the semiconductor chip.

6. The semiconductor device according to claim 1,
wherein the upper surface of the first copper plate includes a region in which the semiconductor chip is mounted via the first metal layer and a region in which the first metal layer is not formed.

7. The semiconductor device according to claim 1,
wherein a maximum valley depth (Sv) of each of the roughened surfaces of the first copper plate and the second copper plate is 2.0 μm or more and 3.0 μm or less.

8. The semiconductor device according to claim 1,
wherein, in the upper surface of the first copper plate, surface roughness of a first region not overlapping with the semiconductor chip is greater than surface roughness of a second region overlapping with the semiconductor chip.

9. The semiconductor device according to claim 1,
wherein the upper surface of the first copper plate includes a first region not overlapping with the semiconductor chip and a second region overlapping with the semiconductor chip, and
wherein the second region includes:
a third region that is flatter than surface roughness of the first region; and
a fourth region arranged to surround the third region and having surface roughness greater than surface roughness of the third region.

10. The semiconductor device according to claim 1,
wherein the at least one semiconductor chip includes a plurality of semiconductor chips,
the semiconductor device further comprising leads arranged around the plurality of semiconductor chips, and
wherein the plurality of semiconductor chips is electrically connected to the leads via conductive members.

11. The semiconductor device according to claim 1,
wherein a lower surface of the second copper plate is exposed from the insulating resin.

12. The semiconductor device according to claim 11,
wherein the lower surface of the second copper plate is roughened.

13. The semiconductor device according to claim 12, further comprising a cooler bonded to the lower surface of the second copper plate via a resin sheet.

14. A method of manufacturing a semiconductor device comprising:
(a) preparing a first substrate including an insulating substrate, a first copper plate bonded to an upper surface of the insulating substrate, and a second copper plate bonded to a lower surface of the insulating substrate;
(b) mounting at least one semiconductor chip on the first copper plate of the first substrate via a first metal layer made of silver and a first bonding layer; and
(c) sealing the semiconductor chip and the insulating substrate with an insulating resin,
wherein, in the first substrate prepared in the step (a),
an upper surface of the first copper plate, a side surface of the first copper plate, and a side surface of the second copper plate are each roughened, and
the first metal layer is selectively formed in a chip mounting region of the upper surface of the first copper plate in which the semiconductor chip is mounted in the step (b).

15. The method according to claim 14,
wherein the step (a) includes:
(a1) roughening the upper surface of the first copper plate, the side surface of the first copper plate, and the side surface of the second copper plate;
(a2) after the step (a1), forming a mask such that the chip mounting region is exposed; and
(a3) after the step (a2), selectively forming the first metal layer in the chip mounting region by a plating method, and
wherein, in the step (a2), the mask is formed so as to cover a part of the upper surface of the first copper plate, the side surface of the first copper plate, and the side surface of the second copper plate.

16. The method according to claim 14,
wherein the step (a) includes:
(a1) forming a first mask such that the chip mounting region is exposed;
(a2) after the step (a1), selectively forming the first metal layer in the chip mounting region by a plating method;
(a3) after the step (a2), forming a second mask that selectively covers the first metal layer; and
(a4) after the step (a3), roughening the upper surface of the first copper plate, the side surface of the first copper plate, and the side surface of the second copper plate while the second mask is formed, and
wherein, in the step (a1), the first mask is formed so as to cover a part of the upper surface of the first copper plate, the side surface of the first copper plate, and the side surface of the second copper plate.

17. The method according to claim 14,
wherein the step (a) includes:
(a1) forming a first mask so as to selectively cover the chip mounting region;
(a2) after the step (a1), roughening the upper surface of the first copper plate, the side surface of the first copper plate, and the side surface of the second copper plate while the first mask is formed;
(a3) after the step (a2), forming a second mask covering at least a part of a roughened region of the upper surface of the first copper plate, the entire side surface of the first copper plate, and the entire side surface of the second copper plate; and
(a4) after the step (a3), selectively forming the first metal layer in the chip mounting region by a plating method while the second mask is formed, and
wherein, in the step (a1), the first mask is formed such that the chip mounting region of the upper surface of the first copper plate is selectively covered and the side surface of the first copper plate and the side surface of the second copper plate are exposed.

18. The method according to claim 17,
wherein, in the step (a4), the first metal layer is formed so as to extend across a non-roughened region and a part of a roughened region of the upper surface of the first copper plate.
